(19) United States
(12) Patent Application Publication
(10) Pub. No.: US 2004/0113048 A1
(43) Pub. Date: Jun. 17, 2004

(54) Image sensor module

(76) Inventor: Hsiu Wen Tu, Hsinchu Hsien (TW)

Correspondence Address: PRO-TECHTOR INTERNATIONAL, 20775 Norada Court, Saratoga, CA, 95070-3018, US

(21) Appl. No.: 10/321,912

(22) Filed: Dec. 16, 2002

(51) Int. Cl. H01L 27/00

(52) U.S. Cl. 250/208.1

(57) ABSTRACT

An image sensor module includes a lens barrel and an image sensor. The lens barrel has an upper end face, a lower end face, an external thread formed between the upper end face and the lower end face, and a transparent region formed within the lens barrel. The image sensor has a first end portion and a second end portion. A transparent layer is provided at the first end portion. An internal thread is formed above the first end portion of the image sensor to engage with the external thread of the lens barrel. Optical signals may pass through the transparent region of the lens barrel and travel to the transparent layer.

### BACKGROUND OF THE INVENTION

1. Field of the Invention

The invention relates to an improved structure for an image sensor module, and in particular to an image sensor module, which is easy to be assembled/disassembled and has fewer components.

2. Description of the Related Art

Referring to FIG. 1, a conventional image sensor module includes a lens holder 10, a lens barrel 20, and an image sensor 30. The lens holder 10 has an upper end face 12, a lower end face 14 and an opening 16 penetrating through the lens holder 10 from the upper end face 12 to the lower end face 14. An internal thread 18 is formed on an inner wall of the opening 16 of the lens holder 10. The lens barrel 20 formed with an external thread 22 is inserted from the upper end face 12 of the lens holder 10, received within the opening 16, and screwed to the internal thread 18 of the lens holder 10. The lens barrel 20 is formed with a transparent region 24 under which an aspheric lens 26 and an infrared filter 28 are arranged in sequence. The image sensor 30 has a first surface 32 and a second surface 34 opposite to the first surface 32 on which a transparent layer 36 is arranged. The image sensor 30 is bonded to the lower end face 14 of the lens holder 10 through the transparent layer 36. The screwed length between the lens barrel 20 and the lens holder 10 may be adjusted to control the distance from the aspheric lens 26 of the lens barrel 20 to the transparent layer 36 of the image sensor 30.

The above-mentioned image sensor module has the following drawbacks.

1. Because the image sensor 30 is bonded to the lower end face 14 of the lens holder 10 through the transparent layer 36, the image sensor 30 cannot be replaced when the image sensor 30 of the module is damaged. In this case, the overall module has to be treated as waste material, and other good elements in the module may not be recycled.

2. Because the transparent layer 36 is bonded to the lower end face 14 of the lens holder 10 by the adhesive, which may contaminate the surface of the transparent layer 36, poor optical signals may be obtained.

3. When the module is assembled, the transparent layer 36 has to be precisely positioned with the aspheric lens 26 and then bonded to the lens barrel 20. Once the positional precision deviates from the standard level, the overall module cannot be reassembled and has to be treated as waste material 4. The lens holder 10 has to be additionally provided to combine the lens barrel 20 with the image sensor 30.

It is an important subject of the invention to provide an improved structure for an image sensor module, which is easy to be assembled/disassembled and has less components.

### SUMMARY OF THE INVENTION

An object of the invention is to provide an image sensor module, which is easy to be assembled/disassembled and can be recycled.

Another object of the invention is to provide an image sensor module with a smaller size so as to meet the miniaturized requirements.

Still another object of the invention is to provide an image sensor module having fewer components so as to lower the manufacturing costs.

To achieve the above-mentioned objects, an image sensor module of the invention includes a lens barrel and an image sensor. The lens barrel has an upper end face, a lower end face, an external thread formed between the upper end face and the lower end face, and a transparent region formed within the lens barrel. The image sensor has a first end portion and a second end portion. A transparent layer is provided at the first end portion. An internal thread is formed above the first end portion of the image sensor to engage with the external thread of the lens barrel. Optical signals may pass through the transparent region of the lens barrel and travel to the transparent layer.

### BRIEF DESCRIPTION OF THE DRAWINGS

FIG. 1 is a schematic illustration showing a conventional image sensor module.

FIG. 2 is an exploded, cross-sectional view showing the image sensor module according to one embodiment of the invention.

FIG. 3 is a cross-sectional view showing the combined image sensor module of the invention.

FIG. 4 is a cross-sectional view showing the image sensor module according to another embodiment of the invention.

FIG. 5 is a cross-sectional view showing the image sensor module according to still another embodiment of the invention.

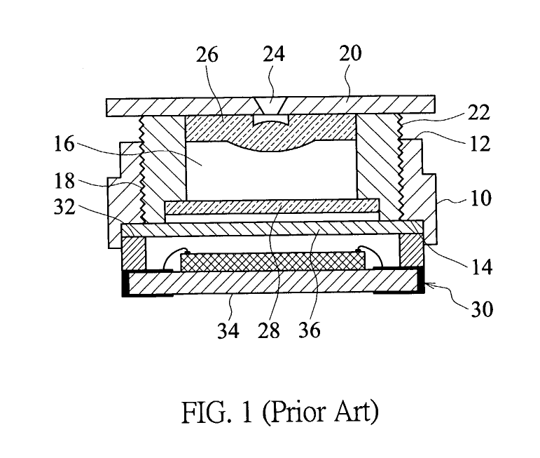

### DETAILED DESCRIPTION OF THE INVENTION

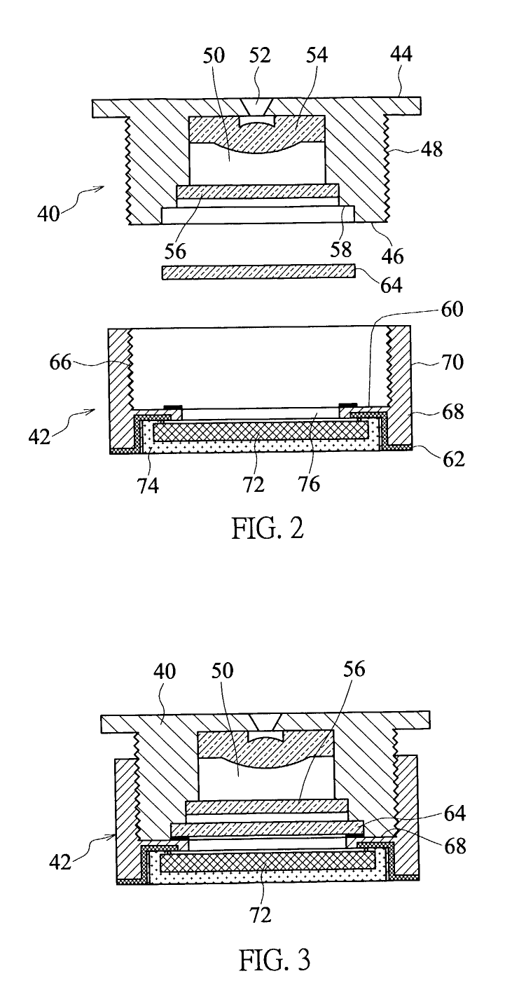

Referring to FIG. 2, an image sensor module of the invention includes a lens barrel 40 and an image sensor 42.

The lens barrel 40 has an upper end face 44, a lower end face 46, an external thread 48 formed between the upper end face 44 and the lower end face 46, and a transparent region 50 defined within the lens barrel 40. An opening 52 communicating with the transparent region 50 is formed on the upper end face 44. An aspheric lens 54 is arranged within the transparent region 50 and closed to the upper end face 44. An infrared filter 56 is arranged within the transparent region 50 and opposite to the aspheric lens 54. A recess 58 is formed at the lower end face 46 of the lens barrel 40.

The image sensor 42 has a first end portion 60 and a second end portion 62. A transparent layer 64, which may be received within the recess 58 of the lens barrel 40, is provided at the first end portion 60. An internal thread 66 is formed above the first end portion 60 of the image sensor 42 to engage with the external thread 48 of the lens barrel 40. Thus, the image sensor 42 and the lens barrel 40 may be combined and the focal length for optical signals may be adjusted by screwing one of the image sensor 42 and the lens barrel 40. Then, the optical signals may pass through the transparent region 50 of the lens barrel 40 and then travel to the transparent layer 64.

In this embodiment, the image sensor 42 includes a substrate 68, a frame layer 70, a photosensitive chip 72 and the transparent layer 64. The substrate 68 and the frame layer 70 may be integrally formed by way of injection molding or mold pressing. The internal thread 66 is formed at an inner wall of the frame layer 70. A concave portion 74 is formed at a bottom surface of the substrate 68. The photosensitive chip 72 is arranged within the concave portion 74 and is electrically connected to the substrate 68 in a flip chip manner. The substrate 68 is further formed with a hollow region 76. The transparent layer 64, which may be a piece of transparent glass, may be placed above the hollow region 76 to cover it. Thus, the photosensitive chip 72 may receive optical signals passing through the transparent layer 64.

As shown in FIG. 3, the transparent layer 64 of the image sensor 42 may be bonded to the substrate 68 to complete the package of the image sensor 42. Then the lens barrel 40 and the image sensor 42 are screwed together. In this case, the transparent layer 64 is arranged within the recess 58 of the lens barrel 40. Thus, the overall image sensor module may be assembled and the image sensor 42 may receive optical signals passing through the transparent region 50 of the lens barrel 40.

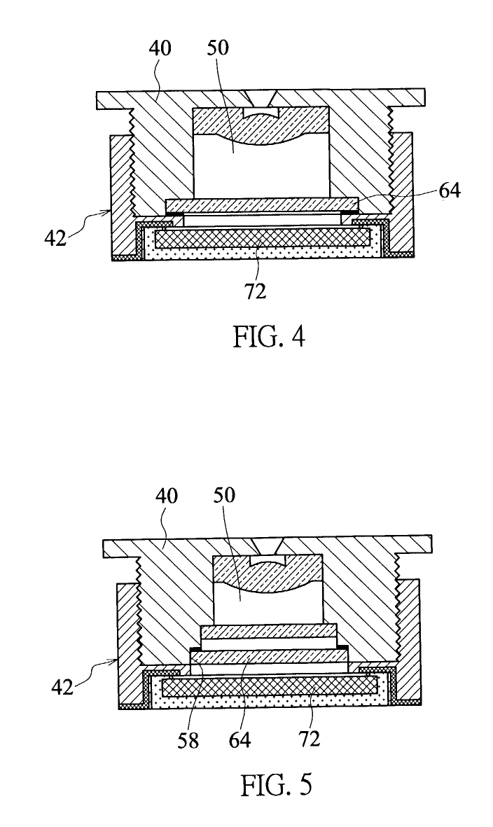

As shown in FIG. 4, the transparent layer of the image sensor 42 may be combined with the infrared filter of the lens barrel 40 to form a single transparent layer 64 capable of filtering infrared beams. Accordingly, the number of components may be decreased and the assembling processes may be simplified.

As shown in FIG. 5, the transparent layer 64 of the image sensor 42 may be bonded to the recess 58 of the lens barrel 40. Then, the image sensor 42 and the lens barrel 40 are screwed together. In this case, the photosensitive chip 72 may also receive optical signals passing through the transparent region 50 of the lens barrel 40 and the transparent layer 64.

Therefore, the invention has the following advantages.

1. Since the image sensor 42 and the lens barrel 40 are screwed together through the internal thread 66 and the external thread 48, the module is easy to be assembled/disassembled so as to facilitate the replacement of the components and the source recycling.

2. Since the conventional lens holder is omitted, the product size may be reduced.

3. Since the conventional lens holder is omitted, the number of components may be reduced, the manufacturing processes may be simplified, and the manufacturing costs may be lowered.

While the invention has been described by way of examples and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. An image sensor module, comprising:
a lens barrel having an upper end face, a lower end face, an external thread formed between the upper end face and the lower end face, and an transparent region formed within the lens barrel; and
an image sensor having a first end portion and a second end portion, a transparent layer being provided at the first end portion, an internal thread being formed above the first end portion of the image sensor to engage with the external thread of the lens barrel, wherein optical signals pass through the transparent region of the lens barrel and travel to the transparent layer.

2. The image sensor module according to claim 1, wherein an opening communicating with the transparent region is formed at the upper end face of the lens barrel, and an aspheric lens and an infrared filter under the aspheric lens are arranged within the transparent region of the lens barrel.

3. The image sensor module according to claim 1, wherein the image sensor includes a substrate, a frame layer arranged on the substrate, a photosensitive chip arranged on the substrate and electrically connected to the substrate, and the internal thread is formed at an inner wall of the frame layer.

4. The image sensor module according to claim 3, wherein the substrate and the frame layer are integrally formed by way of injection molding.

5. The image sensor module according to claim 1, wherein the substrate and the frame layer are integrally formed by way of mold pressing.

6. The image sensor module according to claim 3, wherein a concave portion is formed at a bottom surface of the substrate, the photosensitive chip is arranged within the concave portion and electrically connected to the substrate, and the substrate is formed with a hollow region above which the transparent layer is covered.

7. The image sensor module according to claim 6, wherein the photosensitive chip is electrically connected to the substrate in a flip chip manner.

8. The image sensor module according to claim 1, wherein the transparent layer is a piece of transparent glass.
